(19) United States
(12) Patent Application Publication
(10) Pub. No.: US 2010/0059851 A1
(43) Pub. Date: Mar. 11, 2010

(54) CMOS CIRCUITS COMBINING HIGH VOLTAGE AND RF TECHNOLOGIES

(75) Inventors: John Nigel Ellis, Devon (GB); Paul Ronald Stribley, Devon (GB); Jun Fu, Erfurt (DE)

Correspondence Address: THOMPSON HINE L.L.P.;Intellectual Property Group, P.O. BOX 8801, DAYTON, OH, 45401-8801, US

(73) Assignee: X-FAB SEMICONDUCTOR FOUNDRIES AG, Erfurt (DE)

(21) Appl. No.: 12/306,952

(22) PCT Filed: Jun. 27, 2007
(86) PCT No.: PCT/GB07/50363

§ 371 Date: Oct. 21, 2009

(30) Foreign Application Priority Data
Jun. 30, 2006 (GB) 0612950.6

(51) Int. Cl. H01L 27/08

(52) U.S. Cl. 257/500; 257/E27.046

(57) ABSTRACT

A CMOS circuit comprises at least one high voltage transistor (having gate and drain operating voltages of greater than 8V) and at least one high frequency capable transistor (having a maximum switching frequency of between 100 MHz and 1000 GHz) wherein said transistors are integrated on the same semiconductor substrate so as to allow the simple integration of high voltage circuits and RF (radio frequency) CMOS circuits on the same integrated circuit.

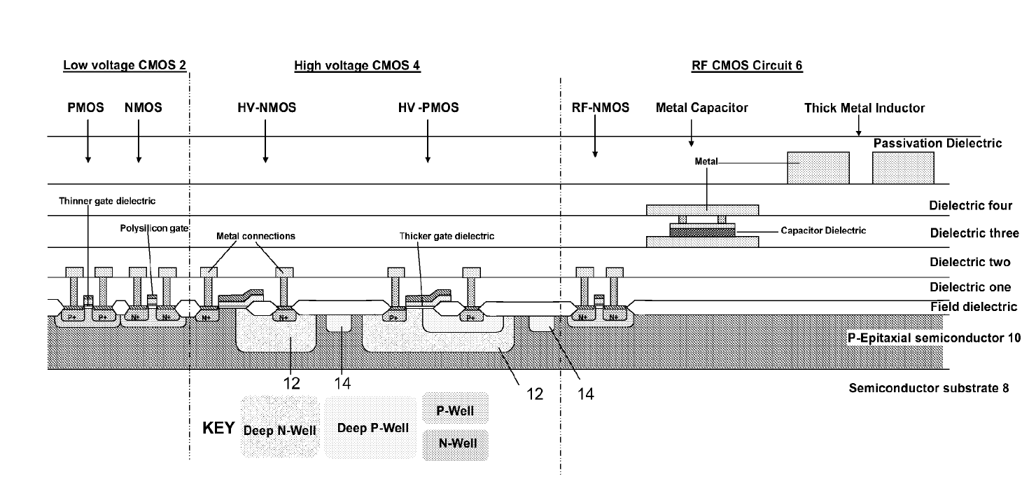

The invention relates to CMOS circuits which combine high voltage and RF technologies.

Modern CMOS technology is capable of providing transistors which have the capability of operating at frequencies of 1 GHz or more. This enables them to provide functionality in radio frequency (RF) communications either for transmitting or receiving, or both. RF communications are increasingly important in today's society as people use more and more personal and portable equipment such as mobile telephones, laptop computers with wireless networking capability and music systems. In automotive applications, car electronics is likely to exploit RF communication links in future for navigation, communication, radar (anti-collision avoidance, steering in difficult conditions like fog) and night vision (IR cameras for fog and night-time identification of animals and people who may be on the road).

RF CMOS circuits are those which can be used for the detection, processing or transmission of radio waves or microwaves which are electromagnetic waves which have a frequency range of about 10 kHz to 1000 GHz. Hence these circuits need to be made from high switching speed capable components which can operate usefully at radio wave or microwave, RF frequencies. RF CMOS components are made using structural configurations which enhance the switching speed capability of the transistors eg by using multiple transistor gates connected in parallel to minimise gate connection series resistances and minimise diode junction parasitic capacitances inherent in the device.

Another field of growing importance is the increasing use of high voltage electronics. High voltage electronics refers to any device which is powered from a power supply voltage rail above the normal supply voltage for that technology. For example, as geometries have shrunk from 1 micron and above, which operated at 5V, to 0.35 micron, the power supply became 3.3V. At smaller geometries the power supply voltage is approximately the technology geometry expressed in microns multiplied by 10. For example, 0.18 micron technology operates from 1.8V; and 0.13 microns from 1.2 to 1.3V. Where such geometries are given (eg. 0.18, 0.35, 1 micron) they refer to the typical CMOS gate length. Automotive systems operate on essentially the 12V standard which has been used for the last 40 years or so. To be able to drive devices at 12V, transistors capable of withstanding 40V for a few seconds is necessary, in order to ensure functionality in the event of a power surge. Transistors which can support these higher voltages need to be designed specifically for these conditions.

Potential applications for RF communications with high voltage applications can be foreseen where high voltage transistors can be controlled through an RF communication link. These can be exploited in mains-operated equipment: for example, switch-mode power supplies; and monitoring equipment, such as industrial controllers; wireless networks such as computer communication systems using infra-red links; and so on where not only are the high voltage transistors required but also high speed transistors to provide communication. In this way it would be possible to establish remote links to security equipment, using RF to communicate with the equipment, while the equipment could switch high voltage devices in applications for displays, power control, equipment control, systems engineering and so on.

The invention provides a CMOS circuit as set out in the accompanying claims.

The invention relates generally to the combination of RF devices and high voltage transistors in the same circuit. RF devices include transistors; capacitors; inductors and variable capacitors developed and characterised for these applications.

In the context of the accompanying claims, high voltage is assumed to be greater than 8V, and low voltage is assumed to be less than 8V. However, the invention also includes embodiments in which the threshold between high and low voltage is assumed to be 5V, rather than 8V. That is, the invention also provides a CMOS circuit as set out in the accompanying claims in which “5V” is substituted for each occurrence of “8V”.

Embodiments of the invention will now be more particularly described, by way of example only, with reference to the accompanying drawing, which shows low voltage, high voltage and RF CMOS circuits formed on the same semiconductor substrate.

In one embodiment, a process developed for high voltage applications is provided for fabricating such transistors which can operate at voltages above the normal supply voltage. Typically this means greater than 3.3V for 0.35 micron technology or greater than 1.8V for 0.18 micron technology. The process comprises a core CMOS technology; combined with additional diffusions which either singly or in multiple combinations provide the means to build transistors which can operate with the drain at a high voltage; or in combination with additional gate oxide thicknesses to enable the input terminal of the transistor (gate in the case of a MOSFET or base in the case of a bipolar) to operate at higher voltages also. The use of multiple diffusions or “wells” enables both the source and drain sides of a transistor to operate at high voltages. This enables devices attached to the circuit to be controlled in the high voltage line, when it is called a high side switch. Drain-only devices can be used on the low side, called a low side switch.

In this patent such technologies are combined with transistors characterised or developed and characterised for RF applications. Transistors for this application means the layout of a device; and characterisation of the device to develop models suitable for circuit design called “compact models” to differentiate between extensive, physics-based models collectively called Technology Computer Aided Design (TCAD) and simpler models used in circuit simulators like SPICE.

Transistors designed for RF include those where consideration of the gate layouts and fingers has been taken into account so as to minimise the gate impedance at RF; and metal wiring to minimise parasitic capacitance which also impedes performance. Characterisation of these devices at RF involves the determination of additional components to account for time delays arising due to a non-zero time-of-flight of electrons or holes across the channel region of the transistor. Typically the additional components needed are a gate resistance and substrate resistance which provide an additional RC time delay to account for non-quasi-static effects at high frequencies.

In the embodiment shown in the FIGURE low voltage 2, high voltage 4 and RF 6 CMOS circuits are formed on a single substrate 8. A core CMOS process having a thick p-epitaxy 10 overlying the P+ substrate 8, and having two diffusion wells to form NMOS and PMOS transistors is extended with two additional wells called a deep lightly doped N well 12, and a deep lightly doped P well 14. Used singly or in combination, it is possible to generate high voltage transistors which can operate at medium voltages (14V) or high voltages (50-80V). In addition, transistors intended for RF applications are built in the core CMOS technology wells using layout styles optimised for low gate resistance and low parasitic capacitances. Together this forms a powerful combination of high voltage devices which can support RF communication links.

A preferred embodiment is described. First, a substrate comprising a silicon wafer which may be lightly doped or heavily doped on which a lightly doped layer is grown, is oxidised. A series of modules is added in which high voltage wells are sequentially masked and implanted, photoresist cleaned off and subsequently the implanted regions are diffused to a suitable depth for the high voltage transistors.

Secondly, the normal CMOS process modules are processed in which further layers of oxide and nitride are grown and deposited, followed by patterning and a further thick oxide is grown. Normal CMOS isolation regions are formed under the thick oxide regions and regions where the thick oxide was prevented from growing. These comprise regions of silicon which are doped more heavily but of similar type to the said layer doping, or more heavily than the said layer doping but of opposite type so that complementary transistors can be made inside these regions.

Thirdly, one or more gate oxides are grown in order to create insulating regions appropriate to the transistors required. For example a 40 nm gate oxide may be required to sustain 20 V while 7 nm may be needed for high performance 0.35 micron, 3.3V transistors. These are formed by a first gate oxidation in which an oxide of perhaps 39 nm is grown, followed by a masking and etch stage which removes this oxide in regions where a thinner oxide is required. Finally, the thin oxide layer is grown which is aimed at the low voltage target. At the same time the thick oxide is increased very slightly.

The next stage is to create low and high voltage transistor gates. The RF transistors are built using standard masking layers in optimised layouts. High voltage gates are also formed through appropriate masking patterns. Some combinations of said low voltage isolation diffusion regions can be utilised in high voltage transistors by appropriate layout.

The process is continued with the formation of LDD regions, spacers at the edges of the polysilicon gates; and silicidation of the gates and active area diffusions. The process is largely completed with the formation of inter-poly to metal dielectric oxide layers, contact regions and metal interconnect lines with one to three layers of metal. Optionally, a fourth layer can be used to increase the interconnect routing capability. Optionally, further layers can be used also. Optionally, the top layer of metal can be made from a thicker metal layer than standard. This enables RF specific components like an inductor to be provided which has an acceptable Q-factor.

Optionally, a metal to metal capacitor can be included between the metal layers whereby a thin dielectric material is added to the metal at one or more stages. This creates a high capacitance per unit area capacitor while offering very low resistance electrodes, thus providing a high Q factor for RF designs.

Using the RF devices with specific layout optimisation and high voltage additional processes, this embodiment provides for RF circuitry together with high voltage capability for a wide range of remote linked applications in commercial and industrial equipment.

1. A CMOS circuit comprising at least one high voltage transistor having gate and drain operating voltages of greater than 8V and at least one high frequency capable CMOS transistor having a maximum switching frequency of between 100 MHz and 1000 GHz wherein said transistors are integrated on the same semiconductor substrate so as to allow the simple integration of high voltage circuits and RF (radio frequency) CMOS circuits on the same integrated circuit.

2. A CMOS circuit as claimed in claim 1, wherein said high frequency capable transistor has a maximum switching frequency of between 100 MHz and 200 GHz.

3. A CMOS circuit as claimed in claim 1 which also includes at least one low voltage transistor having gate and drain operating voltages of less than 8V integrated on the same said semiconductor substrate.

4. A CMOS circuit as claimed in claim 3, wherein said low voltage transistor has a maximum switching frequency of between 100 MHz and 1000 GHz, and can operate at RF frequencies.

5. A CMOS circuit as claimed in claim 3, wherein said low voltage transistor forms part of a circuit arranged for electrical signal processing or for use as a memory, including digital logic, DSP, analog functions, computer processors (CPU), ROM and SRAM.

6. A CMOS circuit as claimed in claim 1, which further comprises one or more deep n-well diffusions and deep p-well diffusions to create regions of high voltage capable transistors.

7. A CMOS circuit as claimed in claim 6, wherein regions of deep n-well diffusions are isolated from each other by regions of deep p-well diffusions.

8. A CMOS circuit as claimed in claim 1, wherein multiple deep n-well diffusions are formed within the same said substrate which have different doping levels to allow optimized high voltage components to be made using them which can then co-exist on the same integrated circuit.

9. A CMOS circuit as claimed in claim 1 wherein low voltage CMOS transistors are fabricated within deep n-well diffusion regions in said substrate, so as to allows them either to interface more easily to high voltage circuits by applying an offset voltage to the n-well, or alternatively to be completely isolated from high voltage circuitry to prevent electrical interference from high voltage circuitry.

10. A CMOS circuit as claimed in claim 1 which also includes on said substrate other components which are useful to create RF circuits, including any or all of the following components: semiconductor diffusion resistors, doped polysilicon resistors, metal resistors, interleaved metal capacitors, interleaved polysilicon capacitors, semiconductor junction diodes, metal semiconductor schottky diodes, diode junction varactors, MOS diode varactors, variable capacitors and greater than 0.5 um thickness metal inductors.

11. A CMOS circuit as claimed in claim 1, which comprises an RF transmission component, and an RF circuit which operates at low voltage less than 8V interfaced on the same substrate to a higher voltage greater than 8V circuit which is arranged to have sufficient voltage and power supplying capability to adequately stimulate said RF transmission component.

12. A CMOS circuit as claimed in claim 11, wherein said RF transmission component is a radio antenna, which can be used to transmit radio waves which can communicate with other remote RF detection circuits.

13. A CMOS circuit as claimed in claim 1, which comprises an RF circuit which operates at low voltage less than 8V interfaced on the same substrate to a higher voltage greater than 8V circuit so that the low voltage RF circuit can efficiently detect and process radio frequency information supplied from a distant source transmitter and then pass on the controlling signals to the latter.

14. A CMOS circuit as claimed in claim 13, wherein said higher voltage circuit is arranged to provide significantly higher voltage supplying capability to control other equipment such as motors or electronic displays which would otherwise be beyond the voltage supplying capability of said low voltage circuit, so that higher voltage (greater than 8V) electrical equipment can be controlled remotely by means of radio wave information transmission using a single integrated circuit.
